(19) United States
(12) Patent Application Publication
(10) Pub. No.: US 2025/0347747 A1
(43) Pub. Date: Nov. 13, 2025

(54) BATTERY MONITORING SYSTEM, BATTERY MONITORING DEVICE, AND VOLTAGE MEASURING DEVICE

(71) Applicants: DENSO TEN Limited, Kobe (JP); DENSO CORPORATION, Kariya-city (JP)

(72) Inventors: Hiroshi OHTANI, Kobe (JP); Shogo SHIGEMORI, Kariya (JP)

(73) Assignees: DENSO TEN Limited, Kobe (JP); DENSO CORPORATION, Kariya-city (JP)

(21) Appl. No.: 19/192,515

(22) Filed: Apr. 29, 2025

(30) Foreign Application Priority Data
May 8, 2024 (JP) 2024-075847

(51) Int. Cl. G01R 31/3842; G01R 31/36; G01R 31/371; G01R 31/392

(52) U.S. Cl. CPC G01R 31/3842; G01R 31/3648; G01R 31/371; G01R 31/392

(57) ABSTRACT

A battery monitoring system includes: a current measuring device configured to measure a current of a battery and output a current value; a voltage measuring device including a voltage measuring circuit that measures a voltage of the battery, a first microcomputer that controls the voltage measuring circuit, and a first wireless communication unit; and a battery monitoring device including a second wireless communication unit, and a second microcomputer to which the current and voltage values are input. The second microcomputer outputs a current measuring request signal to the current measuring device after elapse of a first time based on an output signal from the second wireless communication unit, and the first microcomputer controls the voltage measuring circuit to measure the voltage after elapse of a second time synchronized with the first time based on an output signal from the first wireless communication unit.

### CROSS-REFERENCE TO RELATED APPLICATIONS

This application is based on and claims priorities under 35 USC 119 from Japanese Patent Application No. 2024-075847 filed on May 8, 2024, the content of which is incorporated herein by reference.

### TECHNICAL FIELD

The present disclosure relates to a battery monitoring system, a battery monitoring device, and a voltage measuring device.

### BACKGROUND ART

In the related art, there is a battery monitoring system including a plurality of slave units that measure a voltage of a battery and a master unit that is connected to each slave unit by wireless communication and monitors a state of the battery (for example, see JP2022-062772A). The master unit determines a deterioration state of the battery or the like based on the voltage received from each slave unit and a current of the battery measured by a current sensor.

JP2022-062772A discloses a technique in which, in order to synchronize a voltage measuring timing and a current measuring timing between the slave unit and the master unit, time information managed by the slave unit is transmitted to the master unit, and the master unit synchronizes the current measuring timing with the voltage measuring timing of the slave unit based on the time information.

### SUMMARY

However, in the related art, there is processing that each device performs before and after communication, such as the slave unit adding time information to communication data and the master unit analyzing the communication data received, but such processing may result in variations in processing time.

The variation in the processing time may cause an error between the voltage measuring timing of the slave unit predicted by the master unit and an actual voltage measuring timing of the slave unit. In this case, even if the master unit synchronizes the current measuring timing based on the prediction of the voltage measuring timing, synchronization shift occurs with respect to the actual voltage measuring timing.

Aspects of the present disclosure relate to providing a battery monitoring system, a battery monitoring device, and a voltage measuring device capable of reducing synchronization shift in a measuring timing.

According to an aspect of the present disclosure, there is provided a battery monitoring system including: a current measuring device configured to measure a current of a battery and output a current value; a voltage measuring device including a voltage measuring circuit that measures a voltage of the battery, a first microcomputer that controls the voltage measuring circuit, and a first wireless communication unit that wirelessly outputs a voltage value that is measured; and a battery monitoring device including a second wireless communication unit that wirelessly communicates with the first wireless communication unit, and a second microcomputer to which the current value and the voltage value are input, in which the second microcomputer outputs a current measuring request signal to the current measuring device after elapse of a first time based on an output signal from the second wireless communication unit, and the first microcomputer controls the voltage measuring circuit to measure the voltage after elapse of a second time synchronized with the first time based on an output signal from the first wireless communication unit.

According to aspects of the present disclosure, the measuring timing is set by each device with reference to the timing of communication performed between the measuring device and the battery monitoring device, so that the amount of processing performed before and after communication can be reduced, and the time influence of these processing may be eliminated. Accordingly, it may be possible to reduce the synchronization shift between the voltage measuring timing and the current measuring timing.

### BRIEF DESCRIPTION OF DRAWINGS

Exemplary embodiment(s) of the present invention will be described in detail based on the following figures, wherein:

FIG. 1 is a block diagram illustrating a configuration example of a battery monitoring system according to an embodiment;

FIG. 2A is a diagram illustrating an operation example of the battery monitoring system according to the embodiment;

FIG. 2B is a diagram illustrating the operation example of the battery monitoring system according to the embodiment;

FIG. 3 is a timing chart illustrating processing timings of synchronization processing of a measuring timing;

FIG. 4 is a timing chart illustrating processing timings of the battery monitoring system;

FIG. 5 is a timing chart illustrating another example of the synchronization processing of the measuring timing;

FIG. 6 is a flowchart illustrating a processing procedure of processing performed by a battery monitoring device;

FIG. 7 is a flowchart illustrating a processing procedure of processing performed by a measuring device;

FIG. 8 is a diagram illustrating a configuration example of a battery monitoring system according to a modification;

FIG. 9 is a diagram illustrating the configuration example of the battery monitoring system according to the modification;

FIG. 10 is a flowchart illustrating a processing procedure of processing performed by a TCU according to a modification; and

FIG. 11 is a flowchart illustrating a processing procedure of processing performed by a battery monitoring device according to the modification.

### DESCRIPTION OF EMBODIMENTS

Hereinafter, a battery monitoring system, a battery monitoring device, and a measuring device according to an embodiment will be described in detail with reference to the accompanying drawings. The present disclosure is not limited to the following embodiment. In the following description, “predetermined” can be read as “determined in advance”.

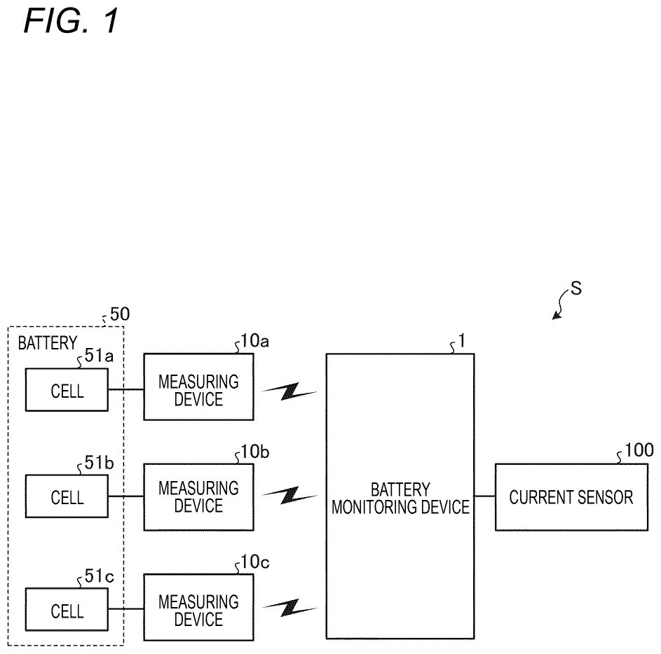

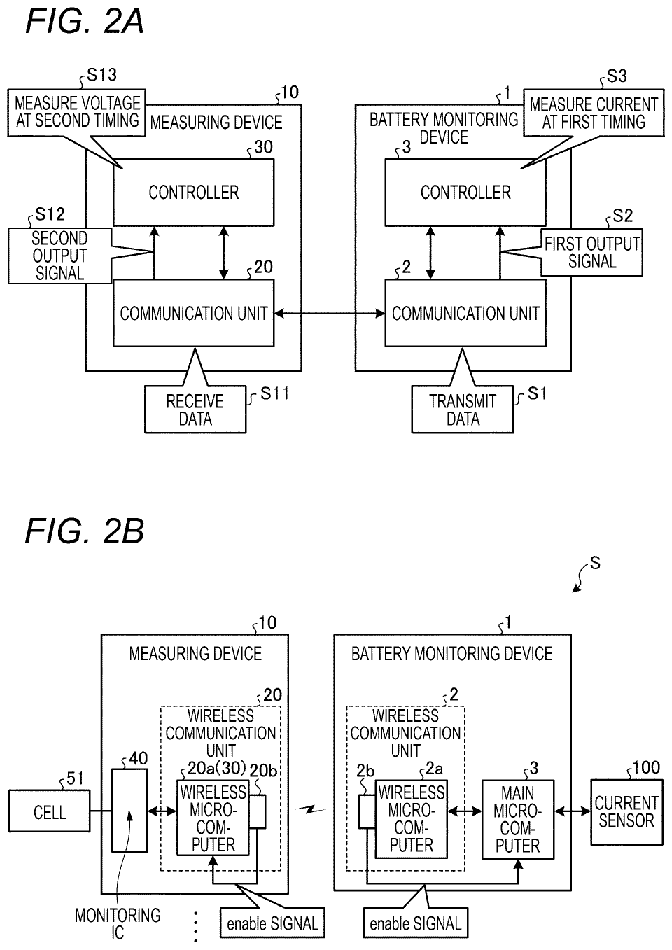

First, an overview of a battery monitoring system according to the embodiment will be described with reference to FIGS. 1, 2A, and 2B. FIG. 1 is a block diagram illustrating a configuration example of a battery monitoring system S according to the embodiment. FIG. 2A and FIG. 2B are diagrams illustrating an operation example of the battery monitoring system S according to the embodiment. A battery monitoring method according to the embodiment is performed by the battery monitoring system S.

The battery monitoring system S according to the embodiment is, for example, a system that monitors a state of a vehicle driving battery (for example, a lithium ion battery) mounted on an electric automatic vehicle or a hybrid automatic vehicle. For example, the battery monitoring system S monitors a deterioration state of the battery. The battery monitoring system S may be configured to monitor a state of any battery other than a battery for a vehicle.

As illustrated in FIG. 1, the battery monitoring system S includes a battery monitoring device 1, a plurality of measuring devices 10a, 10b, and 10c, a battery 50, and a current sensor 100. The battery monitoring system S calculates a cell resistance of the battery 50 from voltage information indicating a voltage output from the battery 50 in which a plurality of cells 51a, 51b, and 51c are connected in series and current information indicating a current flowing through the battery 50, and monitors the deterioration state of the battery 50 based on a resistance value of the cell resistance. In the following description, the plurality of measuring devices 10a, 10b, and 10c are collectively referred to as a plurality of measuring devices 10 unless particularly distinguished. In addition, the plurality of cells 51a, 51b, and 51c are collectively referred to as a plurality of cells 51 unless particularly distinguished.

The plurality of measuring devices 10 is voltage measuring devices that are connected to the plurality of cells 51 constituting the battery 50 and measure voltages (hereinafter referred to as cell voltages) of the plurality of cells 51 in accordance with a voltage measuring instruction of the battery monitoring device 1, respectively.

Specifically, the measuring device 10a measures the cell voltage of the cell 51a, the measuring device 10b measures the cell voltage of the cell 51b, and the measuring device 10c measures the cell voltage of the cell 51c.

For example, the battery monitoring device 1 is communicably connected to the plurality of measuring devices 10 by time division wireless communication, and acquires voltage information indicating the cell voltages from the plurality of measuring devices 10, respectively. Specifically, the battery monitoring device 1 sequentially communicates with the plurality of measuring devices 10 in a communication cycle based on wireless communication. That is, the battery monitoring device 1 is communicably connected to the plurality of measuring devices 10 by a unicast method in which the communication cycle is time-divided and the battery monitoring device 1 sequentially communicates with each of the plurality of measuring devices 10 in a one-to-one manner within a predetermined period. The communication cycle is set to a period that allows the battery monitoring device 1 to complete communication with all the measuring devices 10 with sufficient time to spare, when communication is normally performed.

The current sensor 100 is a current measuring device that measures a current flowing through the battery 50. The current sensor 100 may be provided in the battery monitoring device 1, may be disposed outside the battery monitoring device 1, and may transmit a measured current value to the battery monitoring device 1. In the following description, a case where the current sensor 100 is disposed outside the battery monitoring device 1 and the measured current value is transmitted to the battery monitoring device 1 by wire connection will be described as an example.

In such a configuration, in the battery monitoring system S according to the embodiment, the voltage measuring timings of the plurality of measuring devices 10 and the current measuring timing of the battery monitoring device 1 are synchronized using the communication between the battery monitoring device 1 and the measuring devices 10.

Here, synchronization processing of the measuring timing of the battery monitoring system S according to the embodiment will be described with reference to FIG. 2A and FIG. 2B. In FIGS. 2A and 2B, only one measuring device 10 is illustrated for convenience of 15 description, and actually, the measuring timings are synchronized by communicating with the plurality of measuring devices 10.

First, prior to the description of the synchronization processing of the measuring timing, a functional configuration of each of the battery monitoring device 1 and the measuring device 10 will be described.

As illustrated in FIG. 2A, the battery monitoring device 1 includes a communication unit 2, a controller 3, and a storage unit (not illustrated). The measuring device 10 includes a communication unit 20, a controller 30, and a storage unit (not illustrated).

The communication unit 2 is, for example, a communication integrated circuit (IC) having a BLE (abbreviation for bluetooth low energy. Bluetooth is a registered trademark) communication function. The communication unit 2 sequentially communicates with each of the plurality of measuring devices 10 in a one-to-one manner by time division wireless communication in the communication cycle. That is, the communication unit 2 performs wireless communication in a unicast method. The communication unit 2 performs wired communication with the controller 3 by, for example, an SPI (abbreviation of serial peripheral interface) communication.

The storage unit of the battery monitoring device 1 is, for example, a random access memory (RAM) or a data flash. The storage unit can store voltage information acquired from the measuring device 10, current information acquired from the current sensor 100, information of various programs, and the like. The battery monitoring device 1 may acquire the above programs and various information via another computer or a portable recording medium connected via a wired or wireless network.

The controller 3 includes a microcomputer including a central processing unit (CPU), a read only memory (ROM), a RAM, and the like, and various circuits. The controller 3 controls an operation of the battery monitoring device 1 by the CPU executing a program stored in the ROM using the RAM as a work area. A part or all of the controller 3 may be implemented by hardware such as an application specific integrated circuit (ASIC) or a field programmable gate array (FPGA).

The communication unit 20 is, for example, a communication IC having a BLE communication function. The communication unit 20 performs sequentially communicates with the battery monitoring device 1 in a one-to-one manner by time division wireless communication in the communication cycle. That is, the communication unit 20 performs wireless communication in a unicast method. The communication unit 20 performs wired communication with the controller 30 using, for example, SPI communication.

The storage unit of the measuring device 10 is, for example, a RAM or a data flash. The storage unit can store measured voltage information, information of various programs, and the like. The measuring device 10 may acquire the above programs and various information via another computer or a portable recording medium connected via a wired or wireless network.

The controller 30 includes a microcomputer including a CPU, a ROM, and a RAM, and various circuits. The controller 30 controls an operation of the measuring device 10 by the CPU executing a program stored in the ROM using the RAM as a work area. A part or all of the controller 30 may be implemented by hardware such as an ASIC or an FPGA.

Next, the synchronization processing of the measuring timing will be described.

In the present disclosure, each of the battery monitoring device 1 and the measuring device 10 synchronizes the current measuring timing and the voltage measuring timing based on a output signal output in conjunction with the communication.

First, as illustrated in FIG. 2A, the communication unit 2 transmits communication data including a voltage measuring instruction generated by the controller 3 to the communication unit 20 (step S1). Specifically, the communication unit 2 amplifies power of communication data from a power amplifier circuit (a power amplifier, a first circuit) (not illustrated) and transmits the power to the communication unit 20. Hereinafter, the power amplifier circuit is referred to as PA.

At this time, the communication unit 2 outputs a first output signal indicating that the PA is operating to the controller 3 (step S2). That is, the communication unit 2 outputs the first output signal linked to the transmission of the communication data. More specifically, the communication unit 2 outputs the first output signal indicating start of transmission of the communication data.

When receiving the first output signal, the controller 3 measures the current by the current sensor 100 at a first timing set based on the first output signal (step S3). Specifically, the controller 3 sets a timing at which a predetermined first set time has elapsed from the timing of receiving the first output signal as the first timing. The first set time is a standby time for synchronizing with the voltage measuring timing (a second timing) of the measuring device 10 to be described later.

Next, the communication unit 20 of the measuring device 10 receives the communication data transmitted by the communication unit 2 of the battery monitoring device 1 (step S11). Specifically, the communication unit 20 amplifies a signal of communication data received from an amplifier circuit (a low noise amplifier, a second circuit) (not illustrated). Hereinafter, the amplifier circuit is referred to as LNA.

At this time, the communication unit 20 outputs a second output signal indicating that the LNA is operating to the controller 30 (step S12). That is, the communication unit 20 outputs the second output signal linked to the reception of the communication data. More specifically, the communication unit 20 outputs the second output signal indicating start of reception of the communication data.

When receiving the second output signal, the controller 30 measures the cell voltage from the measuring circuit (not illustrated) at the second timing set based on the second output signal (step S13). Specifically, the controller 30 sets a timing at which a predetermined second set time has elapsed from the timing of receiving the second output signal as the second timing. The second set time is a standby time for synchronizing with the current measuring timing (the first timing) of the battery monitoring device 1. More specifically, the second set time is a time obtained by adjusting the above first set time by a difference between a transmission timing and a reception timing in communication. In addition, since the time of communication is managed based on the time division communication, the difference between the timings is generally substantially constant (that is, a difference between transmission and reception timings is constant).

As described above, in the present disclosure, focusing on the fact that a timing difference between transmission and reception during communication becomes constant, the first set time and the second set time for filling the timing difference with reference to the output signal linked to transmission and reception are set. That is, in the present disclosure, the measuring timing is set with reference to the output signal indicating a timing of communication between the measuring device 10 and the battery monitoring device 1. That is, in the present disclosure, in order to synchronize time, it is not necessary to perform additional processing for time synchronization (processing performed mainly in software processing) in which time information managed by one device is transmitted to the other device. As a result, it is possible to eliminate the influence of the processing performed by each device before and after the communication (the additional processing for the time synchronization). Therefore, it is possible to reduce synchronization shift of the voltage measuring timing and the current measuring timing.

In the present disclosure, by outputting the output signal serving as a reference of the measuring timing to a circuit (hardware) that operates during transmission and reception of the PA, the LNA, or the like, it is possible to eliminate the influence of variation in processing time that occurs when the output of the output signal is temporarily performed in the software processing. That is, according to the present disclosure, by outputting the output signal to the circuit, it is possible to further reduce the synchronization shift of the measuring timing.

Next, the battery monitoring system S will be described in more detail with reference to FIG. 2B. As illustrated in FIG. 2B, the battery monitoring device 1 includes a wireless communication unit 2 (a second wireless communication unit) which is the communication unit 2, and a main microcomputer 3 (a second microcomputer) which is the controller 3. The measuring device 10 includes a wireless communication unit 20 (a first wireless communication unit) which is the communication unit 20, and a monitoring integrated circuit (IC) 40 (a voltage measuring circuit).

The wireless communication unit 2 performs wireless communication with the wireless communication unit 20 of the measuring device 10. The wireless communication unit 2 includes a wireless microcomputer 2a and a transmission and reception circuit 2b. The wireless microcomputer 2a controls wireless communication with the wireless communication unit 20 of the measuring device 10. The transmission and reception circuit 2b includes a power amplifier circuit (PA) that operates during transmission and an amplifier circuit (LNA) that operates during reception. In FIG. 2B, an example is illustrated in which the transmission and reception circuit 2b is disposed outside the wireless microcomputer 2a, and may be built into the wireless microcomputer 2a.

The main microcomputer 3 controls the overall operation of the battery monitoring device 1. Specifically, the main microcomputer 3 performs the above operation of the controller 3.

The wireless communication unit 20 has a function as the communication unit 20 that performs wireless communication with the wireless communication unit 20 of the measuring device 10, and a function as the controller 30 that controls the overall operation of the measuring device 10. The wireless communication unit 20 includes a wireless microcomputer 20a and a transmission and reception circuit 20b. The wireless microcomputer 20a functions as the communication unit 20 that performs wireless communication with the wireless communication unit 20 of the measuring device 10, and the controller 30 that controls the overall operation of the measuring device 10. The transmission and reception circuit 20b includes a power amplifier circuit (PA) that operates during transmission and an amplifier circuit (LNA) that operates during reception. In FIG. 2B, an example is illustrated in which the transmission and reception circuit 20b is disposed outside the wireless microcomputer 20a, and may be built into the wireless microcomputer 20a.

The monitoring IC 40 is a voltage measuring circuit that measures the voltage of the cell 51 in response to a voltage measuring instruction from the wireless microcomputer 20a.

In the configuration illustrated in FIG. 2B, the synchronization processing of the current measuring timing and the voltage measuring timing will be described.

First, the main microcomputer 3 outputs the voltage measuring instruction to the wireless microcomputer 2a, and instructs the wireless microcomputer 2a to transmit the voltage measuring instruction. Upon receiving the voltage measuring instruction, the wireless microcomputer 2a operates the PA in the transmission and reception circuit 2b to transmit the voltage measuring instruction to the measuring device 10. The transmission and reception circuit 2b inputs an enable signal (the first output signal) indicating that the PA is operating during transmission to the main microcomputer 3 as an interrupt signal. In the following, the enable signal indicating that the PA is operating may be referred to as PA enable. By receiving the PA enable as the interrupt signal, the main microcomputer 3 can detect without delay that the voltage measuring instruction is transmitted to the measuring device 10.

Next, the wireless microcomputer 20a of the measuring device 10 receives the voltage measuring instruction transmitted from the battery monitoring device 1 by operating the LNA of the transmission and reception circuit 20b. The transmission and reception circuit 20b inputs an enable signal (the second output signal) indicating that the LNA is operating during reception as an interrupt signal to the wireless microcomputer 20a. In the following, the enable signal indicating that the LNA is operating may be referred to as LNA enable. By receiving the LNA enable as the interrupt signal, the wireless microcomputer 20a can detect without delay that the voltage measuring instruction is received from the battery monitoring device 1.

Then, the battery monitoring device 1 and the measuring device 10 determine the current measuring timing and voltage measuring timing based on the enable signals, and measure the current and the voltage at the determined measuring timings. Specifically, the main microcomputer 3 of the battery monitoring device 1 outputs a current measuring request signal to the current sensor 100 at the first timing set based on the PA enable to measure a current from the current sensor 100. The wireless microcomputer 20a of the measuring device 10 outputs a voltage measuring request signal to the monitoring IC 40 at the second timing set based on the LNA enable to measure the cell voltage by the monitoring IC 40.

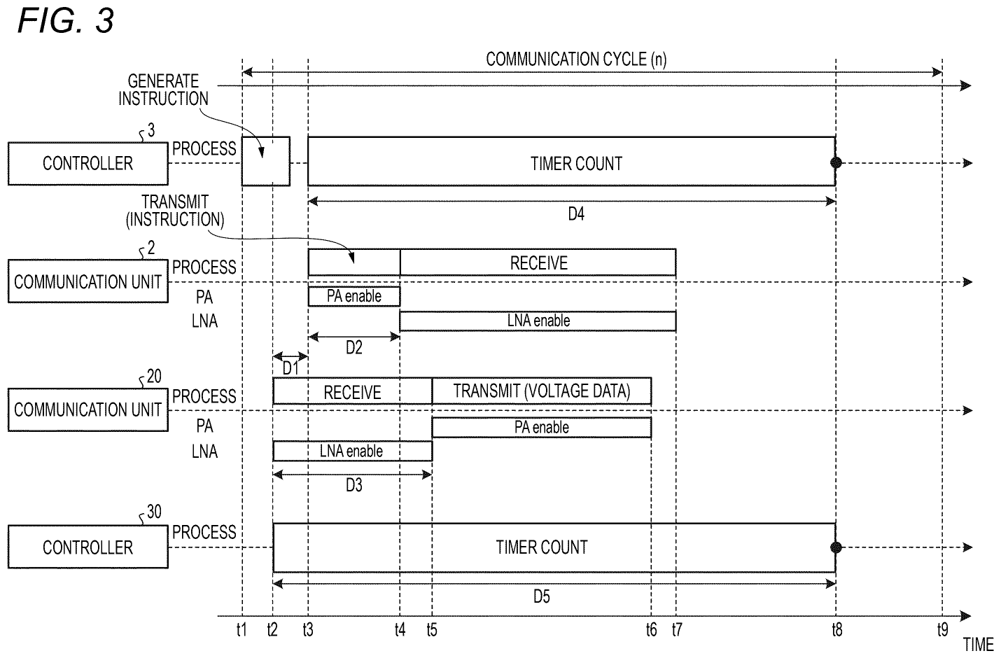

Next, the synchronization processing of the measuring timing will be described in more detail with reference to FIG. 3. FIG. 3 is a timing chart illustrating processing timings of the synchronization processing of the measuring timing. FIG. 3 illustrates a timing chart in one communication cycle (n-th cycle) (from a time point t1 to a time point t9). Although one measuring device 10 (the communication unit 20 and the controller 30) are illustrated in FIG. 3, actually, the voltage measuring timings of all of the plurality of measuring devices 10 and the current measuring timing are synchronized in one communication cycle. That is, after the processing with one measuring device 10 illustrated in FIG. 3, the processing with the other measuring devices 10 is performed in order in one communication cycle (n-th cycle). In addition, in FIG. 3, in one communication cycle, two communication is performed between the battery monitoring device 1 and one measuring device 10, the transmission of the voltage measuring instruction from the battery monitoring device 1 to the measuring device 10 and the transmission of voltage data from the measuring device 10 to the battery monitoring device 1.

Specifically, at the time point t1 corresponding to the start of the communication cycle, the controller 3 generates and outputs a voltage measuring instruction, and instructs the communication unit 2 to transmit the voltage measuring instruction. When the communication unit 2 determines that it is a time point t3, which is a time point after a predetermined period from a start time point t1 of the communication cycle and a transmission timing in the time division communication, the communication unit 2 operates the PA to start the transmission processing of the communication data including the voltage measuring instruction. At this time, the communication unit 2 outputs the PA enable (the first output signal) indicating the start of the operation of the PA to the controller 3. Specifically, the PA enable is output to the controller 3 by an operation of a circuit (hardware) such as the PA. Upon receiving the input of the PA enable, the controller 3 starts counting a timer. Specifically, when the PA enable is input, the controller 3 generates interrupt processing and starts counting the timer.

When the communication unit 20 determines that it is a time point t2 (a time point traced back by a predetermined period D1 from the transmission timing of the time point t3) in the time division communication, which is a time point after a predetermined period from the start time point t1 of the communication cycle, the communication unit 20 operates the LNA to starts the reception processing of the communication data. In other words, the communication unit 20 operates the LNA in advance to prepare for reception leakage of communication data. This is because time management of the time division communication in the communication cycle is performed by the battery monitoring device 1, not the measuring device 10, and the battery monitoring device 1 and the measuring device 10 allow an error in a reference time. Since the error of this time depends on each device characteristic, the error becomes a constant value. Therefore, the predetermined period D1 is set to a value (fixed value) determined in advance based on the constant value. That is, the predetermined period D1 is a period corresponding to a shift time of start timings in transmission and reception processing (an operation of the transmission and reception circuit) between a reception side device and a transmission side device, in other words, a period corresponding to a shift time of output timings of the enable signals output from the transmission side device and the reception side device.

At the time point t2, the communication unit 20 outputs the LNA enable (the second output signal) indicating the start of the operation of the LNA to the controller 30. Specifically, the LNA enable is output to the controller 30 by an operation of a circuit (hardware) such as the LNA. Upon receiving the input of the LNA enable, the controller 30 starts counting the timer. Specifically, when the LNA enable is input, the controller 30 generates interrupt processing and starts counting the timer.

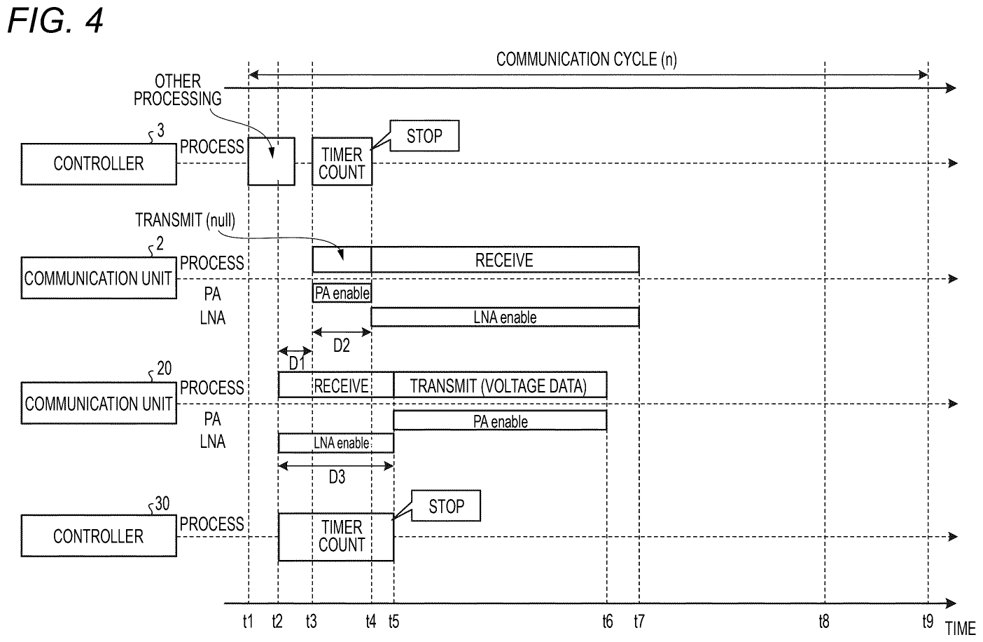

Subsequently, after completing the transmission at a time point t4 after a predetermined period D2 from the time point t3, the communication unit 2 prepares to receive the communication data transmitted from the measuring device 10 by stopping the PA and operating the LNA. FIG. 3 illustrates an example in which the PA is immediately switched to the LNA, and depending on the transmission timing of the measuring device 10, the LNA may be operated after a predetermined period from the stop of the PA. When the predetermined period D2 is out of a normal time range, the controller 3 stops the timer (stops the current measuring processing), which will be described later with reference to FIG. 4.

Next, the communication unit 20 stops the LNA at a time point t5 after a predetermined period from the time point t4, which is a transmission completion timing of the communication unit 2. This is for the same reason as the operation start (the time point t2) of the above LNA, so that reception leakage of communication data does not occur. When the predetermined period D3 during which the LNA is operated is out of the normal time range, the controller 30 stops the timer (stops the voltage measuring processing), which will be described later with reference to FIG. 4.

Subsequently, at the time point t5, the communication unit 20 starts the transmission processing of the communication data to the communication unit 2 by operating the PA. In the transmission processing, the voltage data of the cell voltage measured by the controller 30 in a previous communication cycle ((n−1)-th cycle: a first communication cycle) is transmitted as communication data in a current communication cycle which is the next communication cycle (n-th cycle: a second communication cycle). Then, at a time point t6 after a predetermined period from the time point t5, the communication unit 20 stops the PA when the transmission of the communication data is completed. The communication unit 2 also stops the LNA at a time point t7 after a predetermined period from the time point t6, which is the transmission completion timing of the communication unit 20.

Then, the controller 3 measures the current at a time point t8, which is a timing (the first timing) at which the first set time D4 has elapsed from the time point t3 at which the timer count is started. Specifically, the controller 3 generates timer interrupt processing at the timing at which the first set time D4 has elapsed, and measures the current. The controller 30 measures the cell voltage at the time point t8, which is the timing (the second timing) at which the second set time D5 has elapsed from the time point t2 at which the timer count is started. Specifically, the controller 30 generates timer interrupt processing at the timing at which the second set time D5 has elapsed, and measures the cell voltage. The second set time D5 is a time obtained by adding the predetermined period D1 to the first set time D4. Thus, the controller 3 and the controller 30 can synchronize the current measuring timing and the voltage (cell voltage) measuring timing.

Before the time point t8 at which the current and the voltage are measured, the battery monitoring device 1 and the measuring device 10 determine whether the voltage measuring instruction is transmitted and received. Specifically, the controller 3 of the battery monitoring device 1 measures the current when the voltage measuring instruction is transmitted and the PA enable is received. The controller 30 of the measuring device 10 measures the voltage when the voltage measuring instruction is received and the LNA enable is received. When the measurement of the current and the voltage is completed, history information indicating that the voltage measuring instruction has been transmitted and received is reset.

Then, the controller 3 determines the state of the battery 50 based on the current measured at the first timing in the first communication cycle ((n−1)-th cycle) which is the previous communication cycle and the voltage (the voltage measured in the first communication cycle) received from the measuring device 10 in the second communication cycle (n-th cycle) which is the current communication cycle. Thus, even if the controller 3 receives the voltage data in the next communication cycle, the controller 3 can determine the state of the battery 50 based on the combination of the current and the voltage measured in the same communication cycle.

The battery monitoring system S outputs the first output signal in conjunction with the start of transmission of the communication unit 2, and outputs the second output signal in conjunction with the start of reception of the communication unit 20, a timer starting point can be set early in the communication cycle. That is, the timer is activated at an early timing that is not after another processing is performed from the start of the communication cycle, and thus the error of the time until the timer is started can be reduced to the minimum limit.

The battery monitoring system S may output the first output signal in conjunction with the start of reception (the time point t4) of the communication unit 2, and may output the second output signal in conjunction with the start of transmission (the time point t5) of the communication unit 20. Accordingly, since the set time D4 and D5 from the start of the timer count to the measuring timing can be shortened, the influence of the accuracy error of the timer can be reduced to the minimum limit. In this case, the predetermined period D2 and the predetermined period D3 are fixed times (fixed values).

In FIG. 3, the voltage measuring instruction is generated (output) from the controller 3 at the same timing as the start of the communication cycle, that is, at the time point t1, and may not be the same timing. The timing of generating (outputting) the voltage measuring instruction may be later than the start timing of the communication cycle (the time point t1) or earlier than the start timing of the communication cycle (that is, may be the previous communication cycle).

The timing at which the controller 3 outputs the voltage measuring instruction may not be synchronized in the communication cycle. That is, the controller 3 may output a voltage measuring instruction without a relationship with the communication cycle, and the communication unit 2 may transmit the voltage measuring instruction at a predetermined timing (the time point t3) of the communication cycle after the voltage measuring instruction is output. The transmission timing of the voltage measuring instruction at this time may be the predetermined timing (the time point t3) of the communication cycle that comes closest after the voltage measuring instruction is output.

When it is possible to perform communication with the same measuring device 10 a plurality of times in one communication cycle, the voltage measuring instruction may not necessarily be transmitted at first (first) communication after the start of the communication cycle, or the voltage measuring instruction may be transmitted in second and subsequent communication in the communication cycle. When the voltage measuring instruction is transmitted in the second and subsequent communication, since the predetermined period D1 is fixed, the voltage measuring timing and the current measuring timing can be synchronized in the same way as in the case of transmitting the voltage measuring instruction in the first communication.

In FIG. 3, a length (a time difference) of the period between an output end time point (the time point t4) of the PA enable and an output end time point (the time point t5) of the LNA enable is preferably shorter than a length (a time difference, the predetermined period D1) of the period between an output start time point (the time point t3) of the PA enable and the output start time point (the time point t2) of the LNA enable. This is because, in battery monitoring, while information related to the battery monitoring is expected to be transmitted and received with high reliability, transmission and reception of information related to the battery monitoring are expected to be highly reliable (transmission and reception leakage does not occur), it is difficult for the reception side to predict a transmission time point on the transmission side as compared with the transmission side. On the other hand, this is because the reception side can predict the transmission time (the predetermined period D2) of the communication data to a certain extent, that is, a timing of the transmission end can be predicted, and the timing of the end (the time point t5) can be set to be as close as possible to the end (the time point t4) of the PA enable rather than the start (the time point t2) of the LNA enable signal by using the characteristics. The reason why the end time point (the time point t5) can be predicted is that the communication amount (the voltage measuring instruction, the battery information of the response, or the like) is known in design. That is, since the end time point can be calculated backwards from the start time point compared to the start time point, the timing of which is unknown, it is easy to predict the end time point.

Next, processing when the voltage measuring instruction is not transmitted from the battery monitoring device 1 to the measuring device 10 will be described with reference to FIG. 4. FIG. 4 is a timing chart illustrating the processing timings of the battery monitoring system S. In FIG. 4, the same processing contents as those in FIG. 3 will not be described.

As illustrated in FIG. 4, it is assumed that the controller 3 does not perform the processing of generating the voltage measuring instruction, and performs other processing, at the time point t1, which is the start of the communication cycle. In this case as well, the communication unit 2 operates the PA at the time point t3, which is a transmission timing in time division communication, and starts the transmission processing of communication data. In FIG. 4, it is assumed that the communication data is null. In other words, the communication data includes only the header.

In this case, since the data amount of the communication data transmitted by the communication unit 2 is small, the predetermined period D2 (a period from the time point t3 to the time point t4) in which the transmission processing is performed is shorter than the period for the communication data including the voltage measuring instruction. The predetermined period D2 (the predetermined period D2 in FIG. 3) in the case of transmitting the communication data including the voltage measuring instruction is set within the normal time range. Further, when the predetermined period D2 (the predetermined period D2 in FIG. 4) is out of the normal time range (the predetermined period D2 in FIG. 3), the controller 3 determines that the voltage measuring instruction is not included, and stops counting the timer. That is, the controller 3 stops the current measuring processing in the current communication cycle (n-th cycle). Here, the “normal time range” is not intended to detect abnormal (abnormal) communication, but is a time range for detecting communication for the purpose of measuring current and voltage. That is, the normal time range is a threshold (range) for determining whether the communication is intended to measure the current and the voltage.

Similarly, since the data amount of the received communication data is small (the time of the transmission processing is short) on the communication unit 20 side, the predetermined period D3 (the period from the time point t2 to the time point t5) during which the reception processing is performed is shorter than the period for the communication data including the voltage measuring instruction. The predetermined period D3 (the predetermined period D3 in FIG. 3) in the case of receiving the communication data including the voltage measuring instruction is set within the normal time range. Further, when the predetermined period D3 (the predetermined period D3 in FIG. 4) is out of the normal time range (the predetermined period D3 in FIG. 3), the controller 30 determines that the voltage measuring instruction is not included, and stops counting the timer. That is, the controller 30 stops the voltage measuring processing in the current communication cycle (n-th cycle). As described above, the battery monitoring system S can avoid performing unnecessary current and voltage measuring processing with high accuracy by determining the presence or absence of the voltage measuring instruction in the communication data, after the completion of the transmission and reception of the communication data. In addition, since the battery monitoring system S can easily determine the presence or absence of the voltage measuring instruction using the elapsed time (the predetermined period D2) of the transmission processing and the elapsed time (the predetermined period D3) of the reception processing, it is possible to reduce a processing load of each controller. In addition, since the battery monitoring system S does not measure the voltage and the current every time the communication is performed, but can perform the measuring only when there is a measuring instruction, the processing load can be reduced by reducing unnecessary measuring processing.

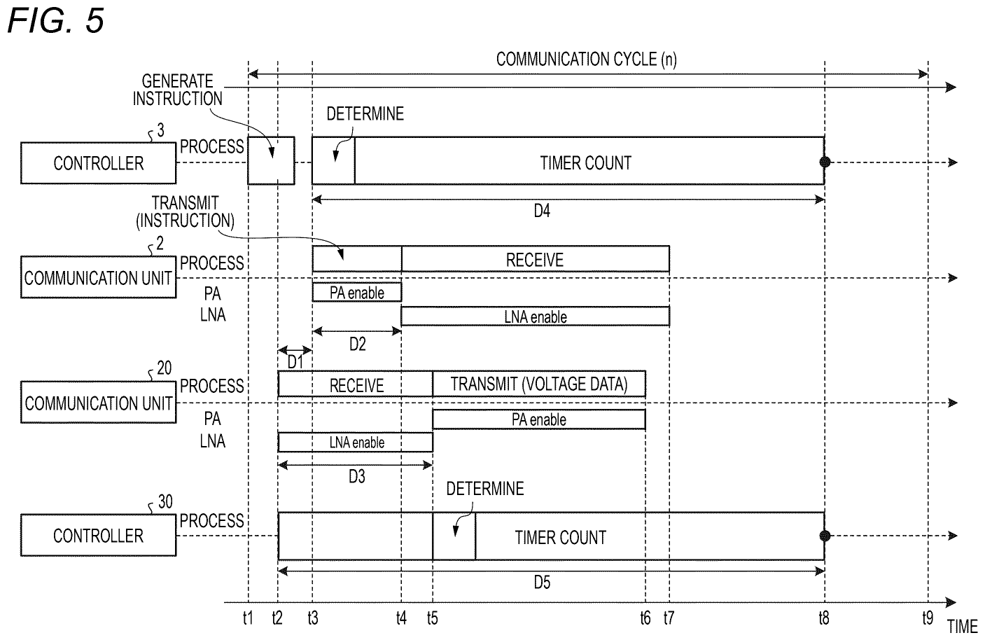

The above processing of the battery monitoring system S is an example. For example, the battery monitoring system S may determine whether the communication data transmitted from the communication unit 2 to the communication unit 20 includes the voltage measuring instruction by a method other than the predetermined periods D2, D3. This point will be described with reference to FIG. 5.

FIG. 5 is a timing chart illustrating another example of the synchronization processing of the measuring timing. In FIG. 5, the same processing contents as those in FIG. 3 will not be described.

In the example of FIG. 5, the communication unit 2 notifies the controller 3 of the data information indicating the content of the transmission data to be transmitted from now at the timing of the time point t3 at which the communication data is transmitted to the communication unit 20. The notification method is, for example, a method performed via an interface such as serial communication.

At the time point t3, the controller 3 starts the timer count, analyzes the content of the transmission data notified from the communication unit 2, and determines whether the transmission data includes the voltage measuring instruction. When the transmission data includes the voltage measuring instruction, the controller 3 continues the timer. When the voltage measuring instruction is included in the transmission data, the controller 3 measures the current at the first timing (the time point t8) at which the first set time D4 has elapsed since the timer started counting. On the other hand, when the voltage measuring instruction is not included in the transmission data, the controller 3 stops the timer and stops the current measuring processing. The controller 3 may start the timer after confirming that the voltage measuring instruction is included in the transmission data. Thus, the controller 3 can avoid a situation in which the current measuring is erroneously performed when the voltage measuring is not performed on the measuring device 10 side with high accuracy.

At the time point t5 at which the reception of the communication data is completed, the controller 30 analyzes the reception data and determines whether the reception data includes the voltage measuring instruction. When the reception data includes the voltage measuring instruction, the controller 30 continues the timer, and when the reception data does not include the voltage measuring instruction, the controller 30 stops the timer. At the time point t4 at which the transmission of the communication unit 2 is completed, in other words, at the time point at which it can be confirmed that no more communication data is being transmitted from the communication unit 2, the controller 30 may perform processing of determining whether the reception data includes the voltage measuring instruction. Thus, the controller 30 can avoid the situation in which the voltage measuring is erroneously performed even though the voltage measuring instruction is not transmitted from the battery monitoring device 1 with high accuracy. In addition, since the battery monitoring system S does not measure the voltage and the current every time the communication is performed, but can perform the measuring only when there is a measuring instruction, the processing load can be reduced by reducing unnecessary measuring processing.

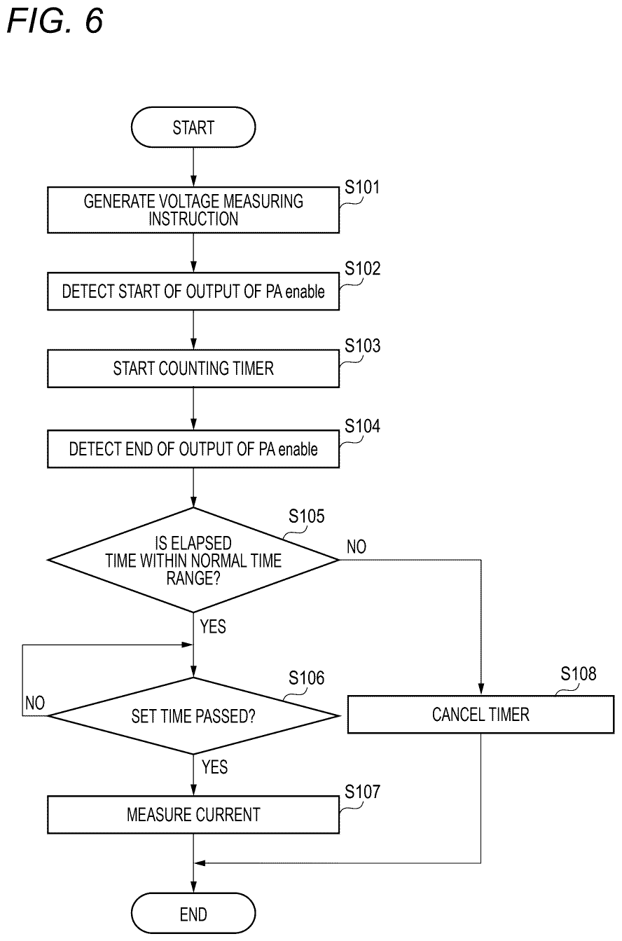

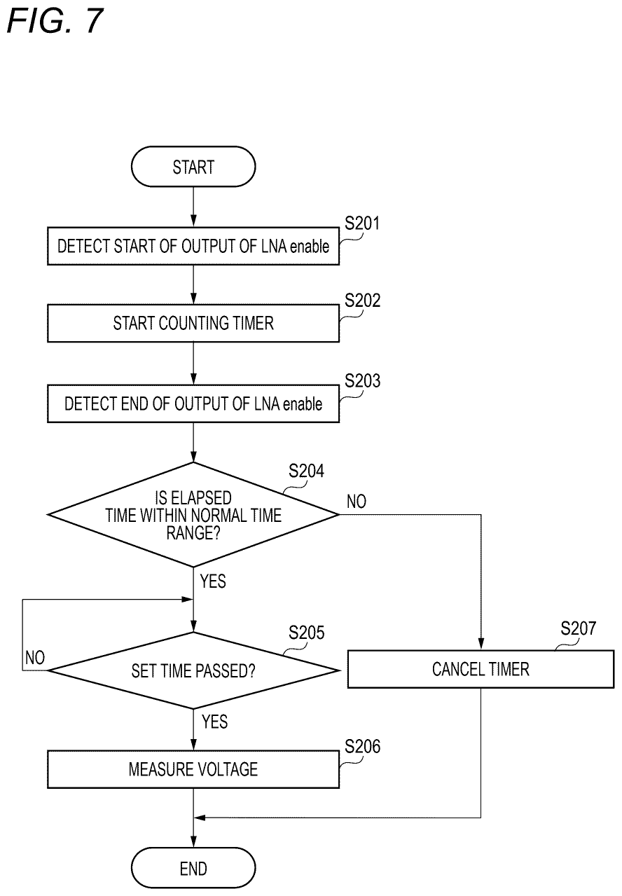

Next, processing procedures of the battery monitoring device 1 and the measuring device 10 will be described with reference to FIGS. 6 and 7. FIG. 6 is a flowchart illustrating a processing procedure of processing performed by the battery monitoring device 1. FIG. 7 is a flowchart illustrating a processing procedure of processing performed by the measuring device 10. FIGS. 6 and 7 illustrate a processing procedure of processing of transmitting the voltage measuring instruction from the battery monitoring device 1 to the measuring device 10.

First, the processing procedure of the battery monitoring device 1 (the controller 3) illustrated in FIG. 6 will be described. Each processing step in FIG. 6 is mainly performed by the controller 3.

First, the controller 3 generates a voltage measuring instruction at the start of the communication cycle (step S101). Subsequently, the controller 3 detects the start of the output of the PA enable indicating that the PA operates during transmission of the communication unit 2 (step S102).

Subsequently, the controller 3 starts counting the timer at the timing at which the input of the PA enable is received (step S103). Subsequently, the controller 3 detects the end of the output of the PA enable associated with the completion of the transmission of the communication unit 2 (step S104).

Subsequently, the controller 3 determines whether the elapsed time (the predetermined period D2 illustrated in FIG. 3) from the start to the end of the transmission of the communication data is within the normal time range (step S105). When the elapsed time is within the normal time range (step S105: Yes), the controller 3 determines whether the ongoing timer has passed the first set time D4 (step S106). When the elapsed time is out of the normal time range (step S105: No), the controller 3 cancels the timer (step S108) and ends the process.

When the ongoing timer has passed the first set time D4 (step S106: Yes), the controller 3 measures the current at the first timing after the elapse of the first set time D4 (step S107), and ends the process. When the timer has not passed the first set time D4 (step S106: No), the controller 3 repeatedly executes step S106 until the timer has passed the first set time D4.

Next, the processing procedure of the measuring device 10 (the controller 30) illustrated in FIG. 7 will be described. Each processing step in FIG. 7 is mainly performed by the controller 30.

First, the controller 30 detects the start of the output of the LNA enable indicating that the LNA operates during reception of the communication unit 20 (step S201).

Subsequently, the controller 30 starts counting the timer at the timing at which the input of the LNA enable is received (step S202). Subsequently, the controller 30 detects the end of the output of the LNA enable associated with the completion of reception of the communication unit 20 (step S203).

Subsequently, the controller 30 determines whether the elapsed time (the predetermined period D3 illustrated in FIG. 3) from the start to the end of the reception of the communication data is within the normal time range (step S204). When the elapsed time is within the normal time range (step S204: Yes), the controller 30 determines whether the ongoing timer has passed the second set time D5 (step S205). When the elapsed time is out of the normal time range (step S204: No), the controller 30 cancels the timer (step S207) and ends the process.

When the ongoing timer has passed the second set time D5 (step S205: Yes), the controller 30 measures the cell voltage at the second timing after the elapse of the second set time D5 (step S206), and ends the process. When the timer has not passed the second set time D5 (step S205: No), the controller 30 repeatedly executes step S205 until the timer has passed the second set time D5.

As described above, the battery monitoring system S according to the embodiment includes the current measuring device (the current sensor 100) that measures the current of the battery 50 and outputs the current value, the measuring device 10 that includes the voltage measuring circuit (the monitoring IC 40) that measures the voltage of the battery 50, the first microcomputer (the wireless microcomputer 20a) that controls the voltage measuring circuit, and the first wireless communication unit 20 that wirelessly outputs the measured voltage value, and the battery monitoring device 1 that includes the second wireless communication unit 2 that wirelessly communicates with the first wireless communication unit 20 and the second microcomputer (the main microcomputer 3) to which the current value and the voltage value are input. The second microcomputer outputs a current measuring request signal to the current measuring device after elapse of a first time (the predetermined period D4) based on the output signal from the second wireless communication unit 2. The first microcomputer controls the voltage measuring circuit to measure the voltage after elapse of a second time (the predetermined period D5) synchronized with the first time has elapsed, based on the output signal from the first wireless communication unit 20.

According to the present disclosure, the measuring timing is set with reference to the output signal indicating the timing of communication between the measuring device 10 and the battery monitoring device 1. As a result, since the influence of the processing performed by each device before and after the communication can be eliminated, the synchronization shift between the voltage measuring timing and the current measuring timing can be reduced.

In the present disclosure, by outputting an output signal serving as a reference of the measuring timing to a circuit such as the PA or the LNA, it is possible to eliminate the influence of variation in the processing time that occur when the output of the output signal is temporarily performed in the software processing. That is, according to the present disclosure, by outputting the output signal to the circuit, it is possible to further reduce the synchronization shift of the measuring timing.

In the above-described embodiment, the configuration in which the voltage measuring instruction is transmitted from the battery monitoring device 1 to the measuring device 10 is illustrated, the current measuring instruction may be transmitted from the measuring device 10 to the battery monitoring device 1.

In the processing of the synchronization adjustment in the second time (the predetermined period D5) obtained by performing synchronization adjustment of the first time (the predetermined period D4) (adding or subtracting the predetermined period D1), the first time and the second time after the synchronization adjustment may be stored in the memory of the product in advance during product shipment or the time may be calculated and set every time the communication is performed during the product operation. Whether the predetermined period D1 is added or subtracted in the synchronization adjustment is changed depending on which device is the transmission side device. In the case of a pattern in which the voltage measuring instruction is transmitted from the battery monitoring device 1 to the measuring device 10 as illustrated in FIG. 3, the synchronization adjustment is processing of adding the predetermined period D1.

However, in the above-described embodiment, the amplifier circuit such as the PA or the LNA is taken as an example of the transmission and reception circuit that outputs the enable signal as the output signal, a modulation circuit or a demodulation circuit may be used as a circuit that outputs an output signal.

The communication units 2 and 20 may further include a control unit (a microcomputer or the like) that controls the transmission and reception circuit and exchanges data with the controllers 3 and 30, in addition to the transmission and reception circuit that performs the transmission and reception processing in specific wireless communication.

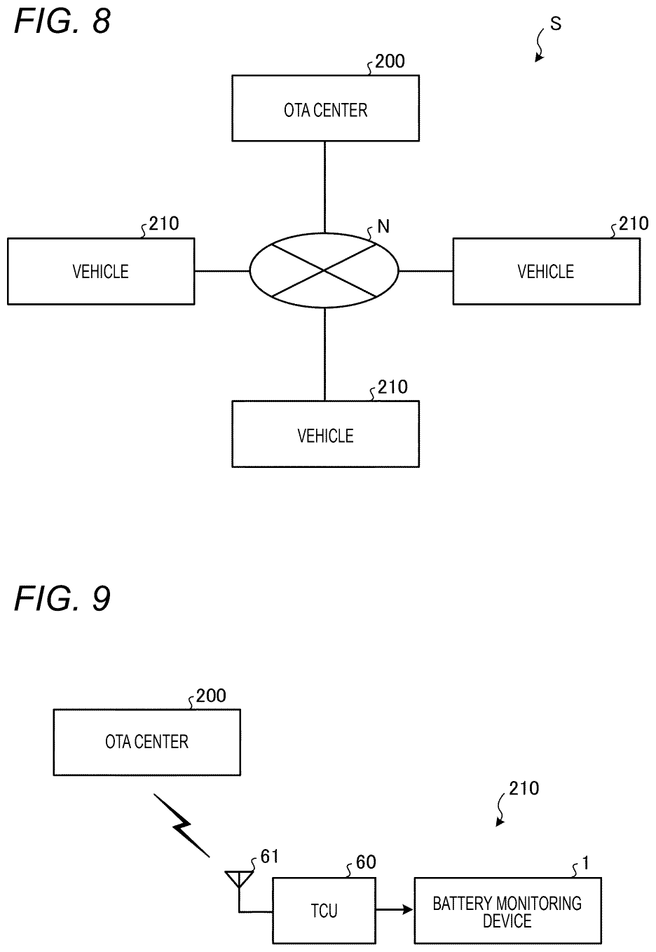

For example, the embodiment described above is an example, the program of the battery monitoring device 1 may be updated by communication between an external server and a vehicle. This point will be described with reference to FIGS. 8 to 11.

FIGS. 8 and 9 are diagrams illustrating a configuration example of the battery monitoring system S according to a modification.

As illustrated in FIG. 8, in the battery monitoring system S according to the modification, an over the air (OTA) center 200 and a vehicle 210 are connected via a communication network N. The communication network N is a wireless communication network such as 5G, LTE, or Wi-Fi (registered trademark).

The battery monitoring system S according to the modification acquires update data for the battery monitoring device 1 and the measuring device 10 from the OTA center 200 and updates the program or the like, by performing wireless communication between the OTA center 200 and the vehicle 210.

As illustrated in FIG. 9, in the battery monitoring system S, each vehicle 210 includes a telematics control unit (TCU) 60 that receives update data from the OTA center 200.

The TCU 60 is an in-vehicle communication unit including an antenna 61 and is for communicating with the OTA center 200 via the communication network N, and performs communication between the OTA center 200 and the vehicle 210 by connecting to the communication network N.

Next, a flow of data update in the battery monitoring system S according to the modification will be described.

When there is a program to be updated, the OTA center 200 transmits update data to the TCU 60 via the communication network N while an ignition switch of the vehicle 210 is turned on. The ignition switch is a power switch of the vehicle.

The TCU 60 transmits the update data received from the OTA center 200 to the communication unit 2 of the battery monitoring device 1 via the antenna 61. Further, the TCU 60 inquires of the OTA center 200 about the update and confirms the presence or absence of update.

In FIG. 9, the communication between the TCU 60 and the battery monitoring device 1 is performed via the communication unit 2 for wireless communication between the antenna 61 for communication with the outside of the vehicle and the measuring device 10, but the communication may also be performed via another communication device, for example, via a wired or wireless in-vehicle local area network (LAN) that communicates between in-vehicle devices such as the TCU 60 or the battery monitoring device 1.

The battery monitoring device 1 stores update data received from the TCU 60 via the communication unit 2 in a storage unit. The update data is stored when the ignition switch is turned on. The storage of the update data is not particularly limited as long as the ignition switch is turned on, and may be while the vehicle is traveling.

When all the download of the update data via the TCU 60 is completed, the battery monitoring device 1 is in an updatable state. When the ignition switch of the vehicle 210 is turned off, the controller 3 of the battery monitoring device 1 performs the update based on the update data stored in the storage unit.

In the modification, the battery monitoring device 1 is automatically updated when the ignition switch is turned off. However, the present disclosure is not limited to the above example. An occupant such as the driver may be notified of the updatable state of the battery monitoring device 1, and may receive whether updating is permitted. The battery monitoring device 1 may be updated when the ignition switch is turned off after the occupant such as the driver has permitted the update.

An example in which the update data of the battery monitoring device 1 is acquired and the program or the like is updated by performing wireless communication between the OTA center 200 and the vehicle 210 described above will be described in a case where the present disclosure is applied.

First, a basic embodiment of the present disclosure will be described regardless of the update using the update data.

As described above, the plurality of measuring devices 10 measure the cell states of the plurality of cells 51 in accordance with the voltage measuring instruction of the battery monitoring device 1. The measuring device 10a measures the cell voltage of the cell 51a, the measuring device 10b measures the cell voltage of the cell 51b, and the measuring device 10c measures the cell voltage of the cell 51c.

For example, the battery monitoring device 1 is communicably connected to the plurality of measuring devices 10 by time division wireless communication, and acquires state information indicating cell states from the plurality of measuring devices 10, respectively. Specifically, the battery monitoring device 1 sequentially communicates with the plurality of measuring devices 10 in the communication cycle based on the wireless communication. That is, the battery monitoring device 1 is communicably connected to the plurality of measuring devices 10 by a unicast method in which the communication cycle is time-divided and the battery monitoring device 1 sequentially communicates with each of the plurality of measuring devices 10 in a one-to-one manner within a predetermined period.

Next, the update of the battery monitoring device 1 based on the update data from the OTA center 200 will be described. The update data corresponds to a battery monitoring program.

In the above-described embodiment, when the communication unit 2 of the battery monitoring device 1 transmits the voltage measuring instruction to each of the plurality of measuring devices 10, the communication unit 2 outputs the first output signal linked to the transmission to the controller 3. The controller 3 performs the current measuring at the first timing set based on the first output signal. In addition, the communication unit 20 of the measuring device 10 outputs the second output signal, which is linked to the reception of the voltage measuring instruction from the battery monitoring device 1, to the controller 30. The controller 30 performs the voltage measuring at the second timing set based on the second output signal. In the above-described embodiment, it is assumed that the battery monitoring program that performs such an operation is installed in advance in the battery monitoring device 1 and the measuring device 10. However, the battery monitoring program may be installed after the update based on the update data from the OTA center 200.

For example, the update data from the OTA center 200 may include a battery monitoring program that causes the communication unit 2 to output the first output signal linked to transmission to the controller 3, when the communication unit 2 transmits the voltage measuring instruction to each of the plurality of measuring devices 10. The update data from the OTA center 200 may include a battery monitoring program that causes the controller 3 to perform the current measuring at the first timing set based on the first output signal. The update data from the OTA center 200 may include a battery monitoring program that causes the communication unit 20 to output, to the controller 30, the second output signal that is linked to the reception of the voltage measuring instruction from the battery monitoring device 1. The update data from the OTA center 200 may be a battery monitoring program that causes the controller 30 to perform the voltage measuring at the second timing set based on the second output signal.

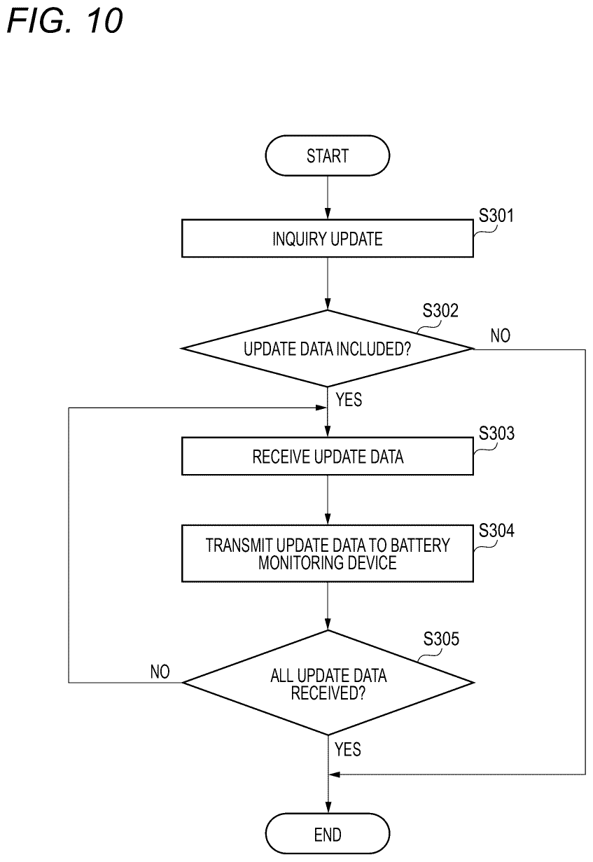

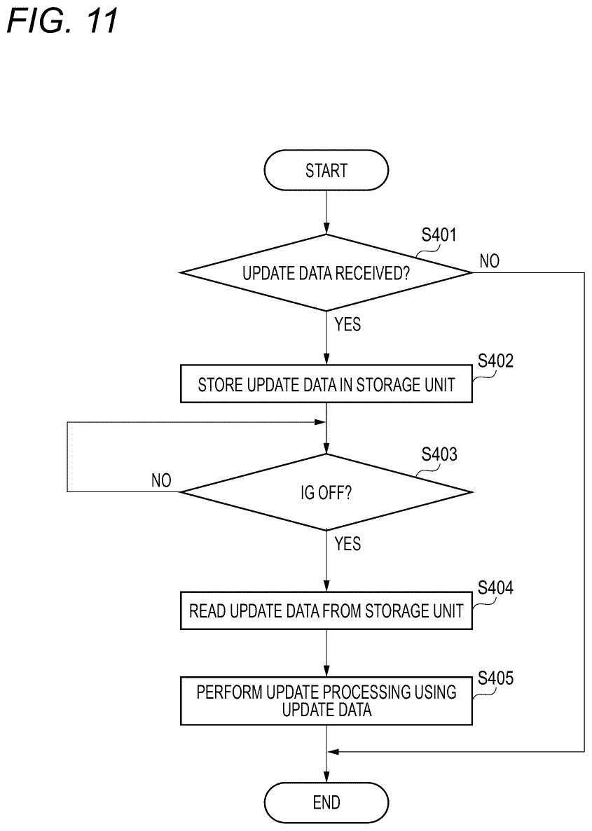

Next, processing in the battery monitoring system S according to the modification will be specifically described with reference to FIGS. 10 and 11. FIG. 10 is a flowchart illustrating a processing procedure of the processing performed by the TCU 60 according to the modification.

As illustrated in FIG. 10, the TCU 60 inquires of the OTA center 200 whether there is update data (step S301). Subsequently, the TCU 60 determines whether the response from the OTA center 200 includes the update data (step S302).

When there is update data (step S302: Yes), the TCU 60 receives the update data from the OTA center 200 (step S303). When there is no update data (step S302: No), the TCU 60 ends the process.

Subsequently, the TCU 60 transmits the received update data to the battery monitoring device 1 (step S304). Specifically, the update data transmitted from the OTA center 200 is associated with identification information indicating a target device, and when the identification information indicates the battery monitoring device 1, the TCU 60 transmits the update data to the battery monitoring device 1.

Subsequently, the TCU 60 determines whether all update data has been received from the OTA center 200 (step S305), and when all the update data has been received (step S305: Yes), the process ends. When the TCU 60 does not receive all the update data (step S305: No), that is, when the update data to be received exists in the OTA center 200, the TCU 60 returns to step S303 and receives the update data again.

Next, FIG. 11 is a flowchart illustrating a processing procedure of processing performed by the battery monitoring device 1 according to the modification. As illustrated in FIG. 11, the battery monitoring device 1 determines whether update data has been received from the TCU 60 (step S401).

When the update data has been received from the TCU 60 (step S401: Yes), the battery monitoring device 1 stores the received update data in the storage unit (step S402). When the update data is not received (step S401: No), the battery monitoring device 1 ends the process.

Subsequently, the battery monitoring device 1 determines whether the ignition switch of the vehicle 210 is turned off (step S403). When the ignition switch is turned off (step S403: Yes), the battery monitoring device 1 reads the update data from the storage unit (step S404). When the ignition switch is not turned off (step S403: No), the battery monitoring device 1 repeatedly executes step S403 until the ignition switch is turned off.

Subsequently, the battery monitoring device 1 updates the battery monitoring program based on the read update data (step S405), and ends the process. When the update data of the measuring device 10 is included in the update data, the battery monitoring device 1 transmits the update data to the measuring device 10. Thus, the measuring device 10 can update the battery monitoring program according to the update data.

However, an example in which the battery monitoring device 1 is updated based on update data from the OTA center 200 has been described, but the measuring device 10 may also be updated based on the update data from the OTA center 200.

The battery monitoring device 1, the measuring device 10, and the method thereof described in the present disclosure may be realized by a special purpose computer provided by configuring a processor and a memory that are programmed to execute one or more functions embodied in the battery monitoring program. Alternatively, the battery monitoring device 1, the measuring device 10, and the method thereof described in the present disclosure may be realized by a special purpose computer provided by configuring a processor by one or more special purpose hardware logic circuits.

The battery monitoring device 1, the measuring device 10, and the method thereof described in the present disclosure may be realized by one or more special purpose computers including a combination of a processor and a memory programmed to execute one or more functions and a processor configured by one or more hardware logic circuits. The program may be stored in a computer-readable non-transitory tangible storage medium as an instruction to be performed by the computer.

The storage unit of the battery monitoring device 1 may store a pre-update program even after the update based on the update data is performed. Accordingly, when the update data is abnormal, the operation can be performed using the program before update.

The following configuration may be employed.

The TCU 60 transmits the update data received from the OTA center 200 to the communication unit 20 of the measuring device 10 via the antenna 61. The measuring device 10 stores the update data received from the antenna 61 via the communication unit 20 in the storage unit. When all the download of the update data via the TCU 60 is completed, the measuring device 10 is in an updatable state. When the ignition switch is turned off, the controller 30 of the measuring device 10 performs update based on the update data stored in the storage unit.

The update of the measuring device 10 is not limited to the example described above. The controller 3 of the battery monitoring device 1 may update the measuring device 10 based on the update data.

Further effects and modifications may be easily derived by those skilled in the art. For this reason, broader aspects of the present invention are not limited to the specific details and the representative embodiment illustrated and described above. Therefore, various modifications can be made without departing from the spirit or scope of the general inventive concept as defined by the appended claims and equivalents thereof.

What is claimed is:

1. A battery monitoring system comprising:
a current measuring device configured to measure a current of a battery and output a current value;
a voltage measuring device including
a voltage measuring circuit that measures a voltage of the battery,
a first microcomputer that controls the voltage measuring circuit, and
a first wireless communication unit that wirelessly outputs a voltage value that is measured; and
a battery monitoring device including
a second wireless communication unit that wirelessly communicates with the first wireless communication unit, and
a second microcomputer to which the current value and the voltage value are input, wherein
the second microcomputer outputs a current measuring request signal to the current measuring device after elapse of a first time based on a first status signal from the second wireless communication unit, the first status signal indicating that communication is possible, and
the first microcomputer controls the voltage measuring circuit to measure the voltage after elapse of a second time synchronized with the first time based on a second status signal from the first wireless communication unit, the second status signal indicating that communication is possible.

2. The battery monitoring system according to claim 1, wherein
the second microcomputer causes the second wireless communication unit to transmit a voltage measuring instruction,
the second wireless communication unit outputs the first status signal when transmitting the voltage measuring instruction by wireless communication,
the first wireless communication unit outputs the second status signal when receiving the voltage measuring instruction by wireless communication, and
the first microcomputer controls the voltage measuring circuit to measure the voltage when the voltage measuring instruction is received from the first wireless communication unit.

3. The battery monitoring system according to claim 1, wherein
the second time is a time obtained by adding or subtracting a time difference between timings at which the second status signal from the first wireless communication unit and the first status signal from the second wireless communication unit are output to the first time.

4. The battery monitoring system according to claim 2, wherein
the second time is a time obtained by adding or subtracting a time difference between timings at which the second status signal from the first wireless communication unit and the first status signal from the second wireless communication unit are output to the first time.

5. The battery monitoring system according to claim 1, wherein
the second microcomputer measures an elapsed time from start to end of communication with the voltage measuring device based on the first status signal output from the second wireless communication unit, and stops measuring processing of the current value when the elapsed time is out of a normal time range.

6. The battery monitoring system according to claim 1, wherein
the first microcomputer measures an elapsed time from start to end of communication with the battery monitoring device based the second status signal output from the first wireless communication unit, and stops measuring processing of the voltage value when the elapsed time is out of a normal time range.

7. The battery monitoring system according to claim 1, wherein
the second microcomputer transmits a voltage measuring instruction to the voltage measuring device when measuring the voltage value, and
the first microcomputer stops measuring processing of the voltage value when the voltage measuring instruction is not included in data received from the battery monitoring device.

8. The battery monitoring system according to claim 1, wherein
the first microcomputer transmits the voltage value measured after elapse of the second time in a first communication cycle to the battery monitoring device in a second communication cycle which is a next cycle of the first communication cycle, and
the second microcomputer determines a state of the battery based on the current value measured after elapse of the first time in the second communication cycle and the voltage value received from the voltage measuring device in the second communication cycle.

9. A battery monitoring device wirelessly communicably connected to a voltage measuring device that measures a voltage of a battery, the battery monitoring device comprising:
a wireless communication unit configured to receive a voltage value wirelessly output from the voltage measuring device; and
a microcomputer to which the voltage value and a current value of the battery measured by a current measuring device are input, wherein
the microcomputer outputs a current measuring request signal to the current measuring device after elapse of a second time synchronized with a first time used for setting a measuring timing of the voltage measuring device, based on the status signal from the wireless communication unit, the status signal indicating that communication is possible.

10. A voltage measuring device wirelessly communicably connected to a battery monitoring device to which a current value is input from a current measuring device that measures a current of a battery, the voltage measuring device comprising:
a voltage measuring circuit configured to measure a voltage of the battery;
a microcomputer configured to control the voltage measuring circuit; and
a wireless communication unit configured to wirelessly output a voltage value to the battery monitoring device, wherein
the microcomputer controls the voltage measuring device to measure the voltage after elapse of a second time synchronized with a first time used for setting a measuring timing of the current measuring device based on the status signal from the wireless communication unit, the status signal indicating that communication is possible.
